(19) United States
(12) Patent Application Publication
(10) Pub. No.: US 2008/0196931 A1
(43) Pub. Date: Aug. 21, 2008

(54) Printed circuit board having embedded components and method for manufacturing thereof

(75) Inventors: Sang-Chul Lee, Anyang-si (KR); Won-Cheol Bae, Pyeongtaek-si (KR); Kwan-Kyu Kim, Seocheon-gun (KR); Doo-Hwan Lee, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/010,194

(22) Filed: Jan. 22, 2008

(30) Foreign Application Priority Data
Feb. 15, 2007 (KR) 10-2007-0015931

(51) Int. Cl. H05K 1/02; H05K 3/36

(52) U.S. Cl. 174/260; 29/830

(57) ABSTRACT

A printed circuit board having embedded components and a method for the manufacturing of the printed circuit board are disclosed. The printed circuit board includes: an intermediary insulation layer; a first core board, in which a first component having at least one electrode formed on one side is embedded, stacked on one side of the intermediary insulation layer; a first insulation layer stacked on the first core board such that the first component is covered; a second core board, in which a second component having at least one electrode formed on one side is embedded, stacked on the other side of the intermediary insulation layer; a second insulation layer stacked on the second core board such that the second component is covered; and a first via, which penetrates the first core board and the second core board. The use of this printed circuit board allows highly integrated designs.

### CROSS-REFERENCE TO RELATED APPLICATIONS

This application claims the benefit of Korean Patent Application No. 10-2007-0015931 filed with the Korean Intellectual Property Office on Feb. 15, 2007, the disclosure of which is incorporated herein by reference in its entirety.

### BACKGROUND

1. Technical Field

The present invention relates to a printed circuit board having embedded components and to a method for the manufacturing of the printed circuit board.

2. Description of the Related Art

The development of the printed circuit board having embedded components is currently receiving attention as a part of next-generation multi-functional miniature packaging technology. Along with these advantages of multi-functionality and miniature sizes, the printed circuit board having embedded components also provide an aspect of higher performance, as it can minimize wiring distances in high frequencies of 100 MHz or greater, and in some cases, can improve reliability in the connection of parts by utilizing wire bonding or solder balls, as used in FC (flip chip) assemblies and BGA's (ball grid arrays).

However, in embedding components such as high-density IC's in the printed circuit board according to the related art, there is a high probability that the yield will be affected by problems of difficult heat release and delamination, etc., which can add to an increase in manufacture costs. There is also a need for greater strength to counter the problem of bending in the printed circuit board caused by the reduced thicknesses in current printed circuit boards, as well as a need for improving heat release.

Previous methods of embedding components resulted in structures having components embedded in only one side of a core board or one side of a build-up layer. Such structures, however, are asymmetrical, and thus are inevitably vulnerable to bending in thermal stress environments. Furthermore, these structures pose a limit to increasing the number of components embedded, and utilize only the sides of the components on which the electrodes are positioned.

### SUMMARY

An aspect of the invention is to provide a printed circuit board, and a method for the manufacturing of the printed circuit board, which enables the embedding of multiple components, to maximize function per unit size.

One aspect of the invention can provide a printed circuit board having embedded components, which includes: an intermediary insulation layer; a first core board, in which a first component having at least one electrode formed on one side is embedded, stacked on one side of the intermediary insulation layer; a first insulation layer stacked on the first core board such that the first component is covered; a second core board, in which a second component having at least one electrode formed on one side is embedded, stacked on the other side of the intermediary insulation layer; a second insulation layer stacked on the second core board such that the second component is covered; and a first via, which penetrates the first core board and the second core board.

A copper clad laminate (CCL) can be used for the first core board.

There may be included a second via, which penetrates the first insulation layer and which is electrically connected with the electrode of the first component, where the second via may be formed in a position corresponding with a position of the electrode of the first component.

In certain embodiments, the printed circuit board may have the other side of the first component and the other side of the second component facing each other. Also, the first component and the second component can have the same size and shape, and can be positioned in symmetry with respect to the intermediary insulation layer.

Prepreg of a B-stage can be used for the first insulation layer.

Another aspect of the invention can provide a method of manufacturing a printed circuit board having embedded components. The method may include: providing a first core board, in which a first component is embedded that has at least one electrode formed on one side, and a second core board, in which a second component is embedded that has at least one electrode formed on one side; stacking the first core board and the second core board together with an intermediary insulation layer positioned in-between; and forming at least one first via that penetrates the first core board and the second core board.

The embedding of the first component can be performed by forming a cavity that penetrates the first core board; attaching a support film on one side of the first core board; embedding the first component in the cavity; and stacking a first insulation layer on the first core board such that the first component is covered.

A copper clad laminate (CCL) can be used for the first core board. In certain cases, the method may further include forming a second via, which penetrates the first insulation layer, and which is electrically connected with the electrode of the first component.

The second via can be formed in a position corresponding with a position of the electrode of the first component. The other side of the first component and the other side of the second component may be arranged to face each other.

Also, the first component and the second component can be substantially the same in size and shape, and can be positioned in substantial symmetry with respect to the intermediary insulation layer.

Prepreg of a B-stage can be used for the first insulation layer.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view illustrating a first disclosed embodiment of a printed circuit board having embedded components according to an aspect of the present invention.

FIG. 2 is a cross-sectional view illustrating a second disclosed embodiment of a printed circuit board having embedded components according to an aspect of the present invention.

FIG. 3 is a flowchart illustrating an embodiment of a method of manufacturing a printed circuit board having embedded components according to another aspect of the present invention.

FIG. 4A, FIG. 4B, FIG. 4C, and FIG. 4D, together with FIG. 5A, FIG. 5B, FIG. 5C, and FIG. 5D, are cross-sectional views representing a flow diagram illustrating the method of manufacturing a printed circuit board having embedded components of FIG. 3.

### DETAILED DESCRIPTION

Certain embodiments of the invention will be described below in more detail with reference to the accompanying drawings. Those components that are the same or are in correspondence are rendered the same reference numeral regardless of the figure number, and redundant explanations are omitted.

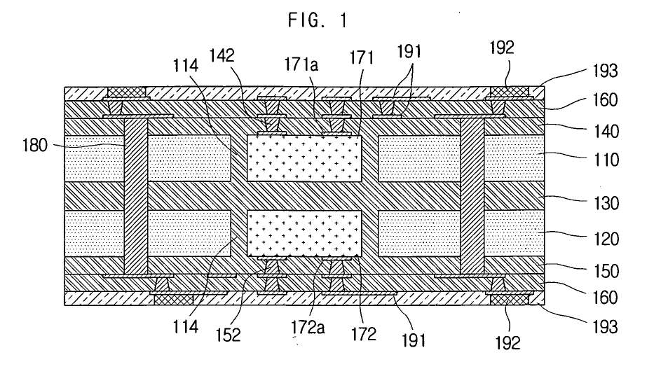

FIG. 1 is a cross-sectional view illustrating a first disclosed embodiment of a printed circuit board having embedded components according to an aspect of the present invention. In FIG. 1 are illustrated a first core board 110, an insulator 114, a second core board 120, an intermediary insulation layer 130, a first insulation layer 140, first vias 180, second vias 142, 152, a second insulation layer 150, lay-up layers 160, a first component 171, a second component 172, electrodes 171a, 172a, circuit patterns 191, lands 192, and solder resists 193.

The intermediary insulation layer 130 may serve to join the first core board 110 and second core board 120 described later. With reference to the arrangement of FIG. 1, the first core board 110 may be stacked on the upper surface of the intermediary insulation layer 130, while the second core board 120 may be stacked on the lower surface of the intermediary insulation layer 130.

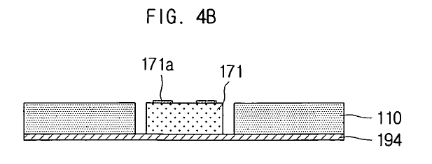

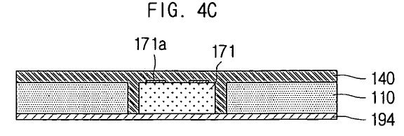

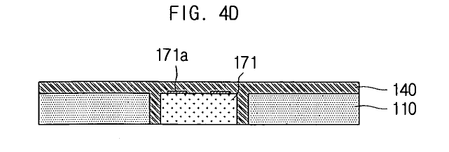

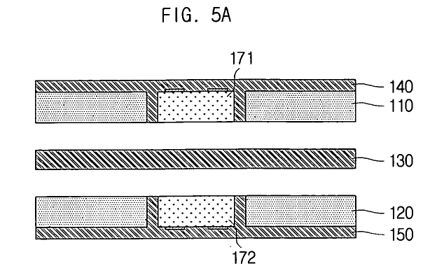

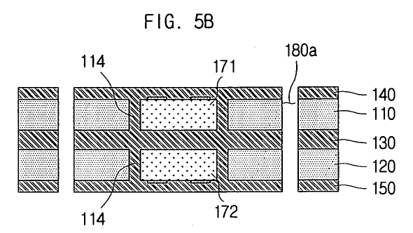

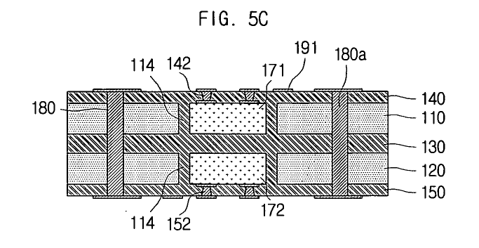

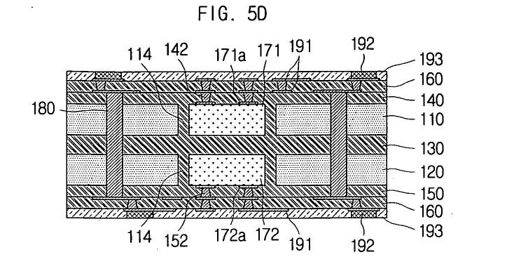

The first core board 110 may be stacked on the upper surface of the intermediary insulation layer 130, and a first component 171 may be embedded in the first core board 110. For this, a cavity 112 (see FIG. 4A) can be formed in the first core board 110. Such a cavity 112 may be formed by methods such as mechanical drilling and laser drilling, or other methods may be used such as chemical etching. As such, the method of forming the cavity may vary as necessary.

In order that the first component 171 may be firmly secured, the cavity formed in the first core board 110 can be made bigger than the first component 171 that will be embedded, with an insulator 114 interposed between the first component 171 and the inner walls of the first core board 110. The insulator 114 will be described later in more detail. The first component 171 may thus be supported by the interposed insulator 114 and may be firmly embedded in the first core board 110.

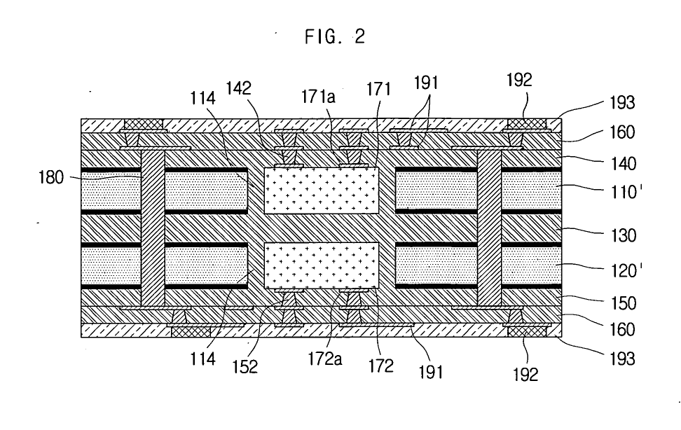

In consideration of heat-releasing performance and structural strength, a copper clad laminate 110′ may be used for the first core board 110, as illustrated in FIG. 2. Using the copper clad laminate can improve heat release and at the same time improve strength in a thermal stress environment.

The second core board 120 may be stacked on a lower surface of the intermediary insulation layer 130, and in the second core board 120 also, a component 172 may be embedded, similar to the first core board 110. Since the structure of the second core board 120 can be substantially the same as that of the first core board 110, the descriptions will not be repeated.

The first core board 110, intermediary insulation layer 130, and second core board 120 stacked as such may serve as a core for the printed circuit board according to this embodiment.

To electrically connect either side of this core, first vias 180 may be formed. A first via 180 can be an IVH (inner via hole) that penetrates the first core board 110, the intermediary insulation layer 130, and the second core board 120.

When implementing a multilayer printed circuit board around the core, a first insulation layer 140 and a second insulation layer 150 may be stacked on the first core board 110 and the second core board 120 respectively, over which lay-up layers 160 may be stacked.

Circuit patterns 191 may be formed on each of the first insulation layer 140, second insulation layer 150, and lay-up layers 160, to perform a pre-designated function, and second vias 142 may also be formed for interlayer conduction. Here, to further improve the degree of integration, the second vias 142 for electrically connecting with the electrodes of the first component 171 can be formed in positions corresponding with the electrodes of the first component, to be put in direct contact with the electrodes. That is, referring to the arrangement of FIG. 1, BVH's (blind via holes), which penetrate the first insulation layer 140 and which are in direct connection with the electrodes, can be formed in positions on the first insulation layer 140 that correspond with the positions where the electrodes of the first component 171 are formed. This structure (152 of FIG. 1) may likewise be applied to the case of the second component.

In the core structured as described above, the first and second component 171, 172 can be embedded such that the electrodes 171a of the first component 171 and the electrodes 172a of the second component face opposite directions. That is, the components can be embedded such that the sides on which the electrodes are not formed face each other. This structure makes it possible to utilize both the upper and lower sides of the core, in a printed circuit board according to this embodiment, whereby the degree of integration can be maximized.

Furthermore, to minimize the occurrence of bending in the core and the printed circuit board itself, it may be theoretically desirable that the first component 171 and second component 172 be of the same size and shape and be symmetrically positioned with respect to the intermediary insulation layer 130. However, as this arrangement is to minimize bending that can be incurred by an asymmetric structure having components embedded in only one side of a core, it will be appreciated that the sameness and symmetry referred to herein not only include mathematically identical and symmetrical cases but also encompass similar structures of substantial symmetry, with which a desired strength can be obtained.

The circuit patterns 191 formed on the outermost layers can be protected by solder resists 193, and lands 192 may also be formed in positions on the circuit patterns 191 for mounting other components.

The structure of a printed circuit board having embedded components according to an aspect of the invention has been described in the foregoing, and now a method of manufacturing a printed circuit board having embedded components according to another aspect of the invention will be described as follows.

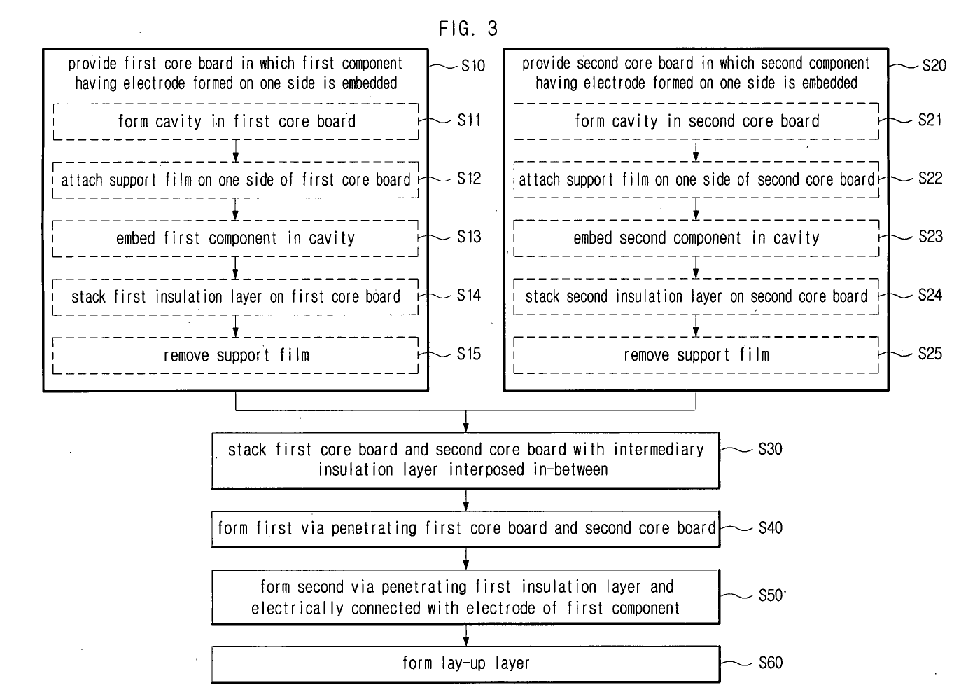

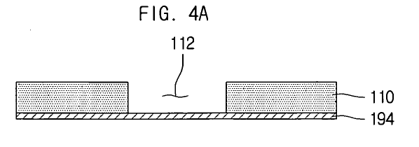

FIG. 3 is a flowchart illustrating an embodiment of a method of manufacturing a printed circuit board having embedded components according to another aspect of the present invention, while FIGS. 4A to 4D and FIGS. 5A to 5D are cross-sectional views representing a flow diagram illustrating the method of manufacturing a printed circuit board having embedded components of FIG. 3. In FIGS. 4A to 4D and FIGS. 5A to 5D, there are illustrated a first core board 110, a cavity 112, an insulator 114, a second core board 120, an intermediary insulation layer 130, a first insulation layer 140, first vias 180, second vias 142, 152, a second insulation layer 150, lay-up layers 160, a first component 171, a second component 172, electrodes 171a, 172a, circuit patterns 191, lands 192, and solder resists 193.

First, a first core board 110, in which a first component having electrodes formed on one side is embedded, and a second core board 120, in which a second component having electrodes formed on one side is embedded, may be prepared (S10, S20).

Before describing the subsequent processes, the procedures for embedding the first component 171 in the first core board 110 will be described.

First, a cavity 112 may be formed in the first core board 110 (S11). For the first cores board 110, a core made of a metal material can be used, or a copper clad laminate can be used.

The cavity 112 can be formed by methods such as mechanical drilling, laser drilling, and chemical etching, and can be formed to penetrate the first core board 110.

Next, a support film 194 may be attached to one side of the first core board 110 (S12). In cases where the cavity 112 is formed to penetrate the first core board 110, it may be difficult to embed the first component 171 in the first core board 110 without a separate means for support. As such, the support film 194 may be attached to one side of the first core board 110, to provide support for the first component 171. FIG. 4A illustrates an example of a first core board 110, in which a cavity 112 is formed, and on one side of which a support film 194 is attached.

It is to be appreciated that the support film 194 can be attached before or after forming the cavity 112 in the first core board 110.

Next, the first component may be embedded in the cavity 112 (S13). Here, the electrodes 171a of the first component can be made to face upwards, with reference to the arrangement in FIGS. 4A to 4D. That is, the side on which the electrodes are not formed may be placed on the support film 194.

Next, a first insulation layer 140 may be stacked on the first core board 110 (S14). B-stage prepreg can be used for the first insulation layer 140. Using prepreg of a B-stage, in which glass fibers are impregnated, may not only allow easy mechanical drilling when later forming vias, but may also effectively suppress bending.

By stacking the first insulation layer 140 on the first core board 110, the insulator 114 can be made to fill in the empty space within the cavity 112. As the first component 171 can be supported by such insulator 114, the first component 171 may be affixed and mounted more securely.

While the insulator 114 can be filled in using a process independent of the stacking of the first insulation layer, by employing the same material as that used for the first insulation layer 140, the insulator 114 can be filled in simultaneously with the stacking of the first insulation layer 140.

Next, the support film attached to the first core board to support the first component may be removed (S15).

By the same method as that described above, the second component may be embedded in the second core board 120 (S21 to S25). The details of this method are substantially the same as those for the first component 171 and thus will not be repeated.

Next, the first core board 110 and the second core board 120 may be stacked with the intermediary insulation layer interposed in-between (30). In this way, a core having two embedded components can be formed (see FIG. 5A). As with the first insulation layer 140 and the second insulation layer 150, prepreg can be used for the intermediary insulation layer.

Here, the first core board 110 and the second core board 120 may be stacked such that the electrodes 171a of the first component and the electrodes 172a of the second component face opposite directions, as illustrated in FIG. 5A. That is, the sides on which the electrodes are not formed can be made to face each other. This structure makes it possible to utilize both the upper and lower sides of the core, in a printed circuit board according to this embodiment, whereby the degree of integration can be maximized.

Also, to minimize the occurrence of bending, it may be desirable that the first component 171 and second component 172 be of the same size and shape and be symmetrically positioned with respect to the intermediary insulation layer 130. However, as this arrangement is to minimize bending that can be incurred by an asymmetric structure having components embedded in only one side of a core, it will be appreciated that the sameness and symmetry referred to herein not only include mathematically identical and symmetrical cases but also encompass similar structures of substantial symmetry, with which a desired strength can be obtained.

Afterwards, first vias 180 may be formed that penetrate the first core board 110 and the second core board 120 (S40, FIG. 5B). The first vias 180 may penetrate the first core board 110 and second core board 120 to serve as conduction paths that interconnect either sides. A first via 180 can be formed by forming a through-hole 180a using mechanical drilling, etc., and then forming a plating layer on the inner wall of the through-hole, or filling the through-hole with a conductive material.

As the first insulation layer 140 may already be stacked on the first core board 110, the first vias 180 may be formed to penetrate also the first insulation layer 140. The same may apply to the second core board 120, if a second insulation layer 150 is stacked.

Next, second vias may be formed that penetrate the first insulation layer to be electrically connected with the electrodes of the first component (S50). Due to the stacking of the first insulation layer 140 on the first core board 110, the first component 171 may be isolated from the exterior. Second vias 142 can be formed in such cases, as illustrated in FIG. 5C, to electrically connect the first component 171 with the exterior.

Here, to further increase the degree of integration, the second vias 142 for electrically connecting with the electrodes 171a of the first component 171 can be formed in positions corresponding with the electrodes 171a of the first component 171, to be put in direct contact with the electrodes 171a. That is, referring to the arrangement shown in FIG. 5C, BVH's (blind via holes), which penetrate the first insulation layer 140 to be in direct connection with the electrodes, can be formed in positions on the first insulation layer 140 that correspond with the positions where the electrodes of the first component 171 are formed. This structure may likewise be implemented for the second component in a similar manner.

Along with forming the second vias 142, pre-designed circuit patterns 191 may be formed on the surfaces of the first insulation layer 140 and second insulation layer 150.

Next, lay-up layers 160 may be formed (S60, FIG. 5D). By additionally forming lay-up layers 160 over the first insulation layer 140, a multilayer printed circuit board may be formed to a desired number of layers. It is to be appreciated that after forming the lay-up layers 160, solder resists 193 may be applied which protect the circuit patterns 191 formed on the outermost layers, and that lands 192 may be formed on which to mount additional components.

According to certain embodiments of the invention as set forth above, components can be embedded in the core, to increase the degree of freedom in planning and allow highly integrated designs. Also, by utilizing a vertically embedded structure, the printed circuit board can be implemented to higher densities, and by utilizing both sides of the core, the degree of integration can be maximized.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A printed circuit board having embedded components, the printed circuit board comprising:
an intermediary insulation layer;
a first core board stacked on one side of the intermediary insulation layer, the first core board having a first component embedded therein, and the first component having at least one electrode formed on one side thereof;
a first insulation layer stacked on the first core board such that the first component is covered;
a second core board stacked on the other side of the intermediary insulation layer, the second core board having a second component embedded therein, and the second component having at least one electrode formed on one side thereof;
a second insulation layer stacked on the second core board such that the second component is covered; and
a first via penetrating the first core board and the second core board.

2. The printed circuit board of claim 1, wherein the first core board is made from a copper clad laminate.

3. The printed circuit board of claim 1, further comprising:
a second via penetrating the first insulation layer and electrically connected with the electrode of the first component,
wherein the second via is formed in a position corresponding with a position of the electrode of the first component.

4. The printed circuit board of claim 1, wherein the other side of the first component and the other side of the second component face each other.

5. The printed circuit board of claim 1, wherein the first component and the second component are substantially the same in size and shape.

6. The printed circuit board of claim 1, wherein the first component and the second component are positioned in symmetry with respect to the intermediary insulation layer.

7. The printed circuit board of claim 1, wherein the first insulation layer includes prepreg.

8. A method of manufacturing a printed circuit board having embedded components, the method comprising:
providing a first core board and a second core board, the first core board having a first component embedded therein, the second core board having a second component embedded therein, the first component having at least one electrode formed on one side thereof, and the second component having at least one electrode formed on one side thereof;
stacking the first core board and the second core board together with an intermediary insulation layer positioned in-between; and
forming at least one first via penetrating the first core board and the second core board.

9. The method of claim 8, wherein embedding the first component is performed by a set of operations comprising:
forming a cavity penetrating the first core board;
attaching a support film on one side of the first core board;
embedding the first component in the cavity; and
stacking a first insulation layer on the first core board such that the first component is covered.

10. The method of claim 9, wherein the first core board is made from a copper clad laminate.

11. The method of claim 9, further comprising:
forming a second via penetrating the first insulation layer and electrically connected with the electrode of the first component.

12. The method of claim 11, wherein the second via is formed in a position corresponding with a position of the electrode of the first component.

13. The method of claim 8, wherein the other side of the first component and the other side of the second component face each other.

14. The method of claim 8, wherein the first component and the second component are substantially the same in size and shape.

15. The method of claim 8, wherein the first component and the second component are positioned in substantial symmetry with respect to the intermediary insulation layer.

16. The method of claim 8, wherein the first insulation layer includes prepreg.
